(19) United States
(12) Patent Application Publication
(10) Pub. No.: US 2026/0352003 A1
(43) Pub. Date: Nov. 5, 2026

(54) CHARGING DOCK WITH CONNECTION STATUS DISPLAY FUNCTION, AND CHARGING DEVICE

(71) Applicant: Shenzhen Deone Innovation Technology Co., Ltd, Shenzhen (CN)

(72) Inventors: HUAYONG XIE, Zhanjiang (CN); LEI YU, Shenzhen (CN); QIANG LIU, Jingzhou (CN)

(21) Appl. No.: 19/727,563

(22) Filed: Jul. 1, 2026

(30) Foreign Application Priority Data
Aug. 12, 2025 (CN) 202521709101.6

(51) Int. Cl. H02J 7/70; H05K 5/00; H05K 5/02

(52) U.S. Cl. CPC H02J 7/70; H05K 5/0018; H05K 5/0226; H05K 5/0247; H05K 5/026; H05K 5/0286

(57) ABSTRACT

The present disclosure provides a charging dock with a connection status display function, and a charging device. The charging dock includes a first main body. The first main body is provided with a first output module electrically connected to a second device and an input module connected to a first device. The charging dock further includes a second main body hinged to the first main body. The second main body is provided with a display module used for displaying an electrical connection status of the first output module and the second device. By arranging the display module on the second main body hinged to the first main body to display the connection status of an electronic device and the first output module, in an unfolded state, users may learn about the connection status of the electronic device and the first output module by observing the display module.

### CROSS-REFERENCE TO RELATED APPLICATIONS

This application claims priority to Chinese Patent Application No. 2025217091016, filed on Aug. 12, 2025, which is hereby incorporated by reference in its entirety.

### TECHNICAL FIELD

The present disclosure relates to the technical field of electronic device accessories, in particular to a charging dock with a connection status display function, and a charging device.

### BACKGROUND

In use of an electronic device, there are times when the electronic device has insufficient power and cannot be used, and in this case, the electronic device needs to be charged. Traditionally, a charging cable needs to be plugged into the electronic device to charge the electronic device. During the process of plugging the charging cable into the electronic device, it is necessary to align the charging cable with an interface of the electronic device, so the operation is relatively complicated.

The charging process of the electronic device may be simplified by placing the electronic device on an output module of a charging dock for charging. When the electronic device is charged by means of the charging dock, the connection status of the electronic device and the output module cannot be easily observed, and there may be cases where the electronic device is not properly connected to the output module. As a result, the electronic device fails to be charged, thereby compromising user experience.

### SUMMARY

In view of the defects and deficiencies in the prior art, an objective of the present disclosure is to provide a charging dock with a connection status display function, and a charging device. A display module is arranged on a second main body hinged to a first main body to display the connection status of an electronic device and a first output module, such that in an unfolded state, users may learn about the connection status of the electronic device and the first output module by observing the display module, to avoid an improper connection between the electronic device and the output module.

To fulfill the above objective, the technical solution adopted by the present disclosure is as follows: a charging dock with a connection status display function includes a first main body, where the first main body is provided with a first output module and an input module, the input module is connected to a first device, and the first output module is electrically connected to a second device; and the charging dock further includes a second main body hinged to the first main body, the second main body is provided with a display module, and the display module is used for displaying an electrical connection status of the first output module and the second device.

By adopting the above technical solution, the present disclosure has the following beneficial effects: the display module is arranged on the second main body hinged to the first main body to display the connection status of an electronic device and the first output module, such that in an unfolded state, users may learn about the connection status of the electronic device and the first output module by observing the display module, to avoid an improper connection between the electronic device and the output module.

### BRIEF DESCRIPTION OF DRAWINGS

To more clearly explain the technical solutions in the embodiments of the present disclosure or the prior art, drawings used for describing the embodiments of the present disclosure or the prior art are briefly introduced below. Obviously, the drawings in the following description merely illustrate some embodiments of the present disclosure, and for those ordinarily skilled in the art, other drawings may be obtained on the basis of the following ones without creative labor.

FIG. 1 is a schematic structural diagram of a charging dock in an unfolded state according to an embodiment of the present disclosure.

FIG. 2 is a schematic structural diagram of the charging dock in a folded state according to an embodiment of the present disclosure.

FIG. 3 is a schematic structural diagram of the charging dock in the unfolded state, from another perspective, according to an embodiment of the present disclosure.

FIG. 4 is a schematic structural diagram of a charging device according to an embodiment of the present disclosure.

FIG. 5 is an exploded view of the charging device according to an embodiment of the present disclosure.

FIG. 6 is an exploded view of a first main body according to an embodiment of the present disclosure.

FIG. 7 is an enlarged view of part B in FIG. 6.

FIG. 8 is an exploded view of a second main body according to an embodiment of the present disclosure.

FIG. 9 is an exploded view of the second main body, from another perspective, according to an embodiment of the present disclosure.

FIG. 10 is an enlarged view of part C in FIG. 9.

FIG. 11 is a sectional view along A-A′ in FIG. 1.

FIG. 12 is a sectional view along A-A′ in FIG. 2.

FIG. 13 is a schematic structural diagram of an adapter according to an embodiment of the present disclosure.

### REFERENCE SIGNS

100, charging dock; 10, first main body; 11, input module; 111, charging interface; 112, information interaction interface; 12, first output module; 121, first output unit; 122, third output unit; 123, first connector; 124, second connector; 13, first hinge portion; 131, first wiring duct; 132, limiting groove; 133, first shaft hole; 14, first receiving chamber; 15, first circuit board; 151, first connecting portion; 16, first shell; 17, second shell; 20, second main body; 21, display module; 211, diffuser; 212, light-shielding portion; 213, light source; 22, second output module; 221, second output unit; 23, storage module; 24, second hinge portion; 241, second wiring duct; 242, limiting portion; 243, second shaft hole; 25, second receiving chamber; 26, second circuit board; 261, second connecting portion; 27, third shell; 28, fourth shell; 30, rotating shaft; 40, magnetic part; 200, adapter; 201, receiving slot; 202, adapting plug; 203, adapting socket; 300, electronic card; X, first direction; Y, second direction.

### DESCRIPTION OF EMBODIMENTS

The present disclosure is described in further detail below in conjunction with the accompanying drawings.

The following specific embodiment is merely used for explaining the present disclosure rather than limiting the present disclosure. After reading the specification, those skilled in the art may make non-creative modifications to this embodiment as needed, and all these non-creative modifications within the scope of the claims of the present disclosure are protected by the patent law.

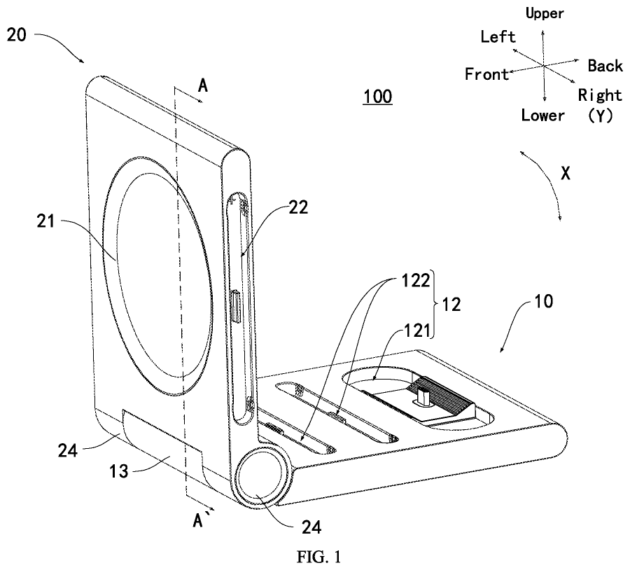

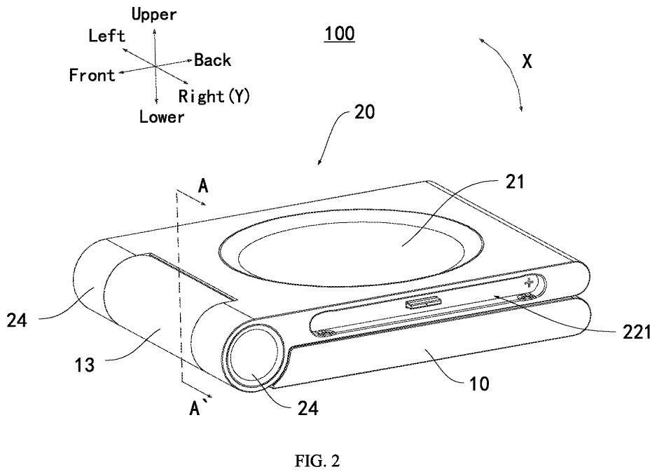

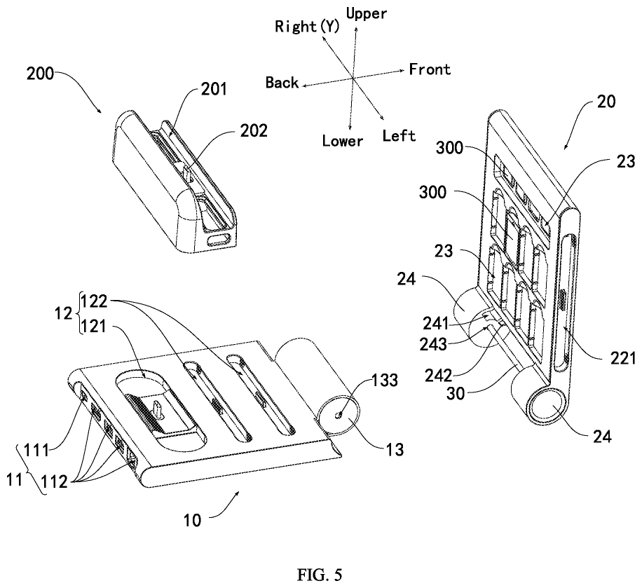

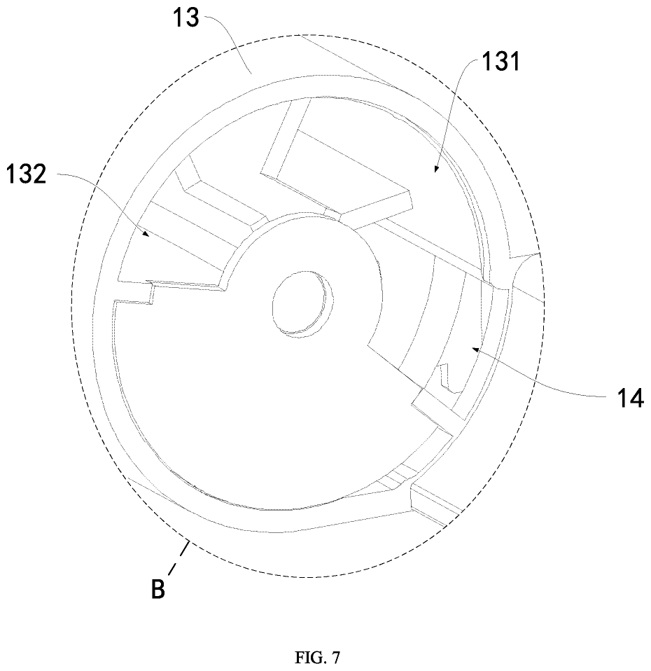

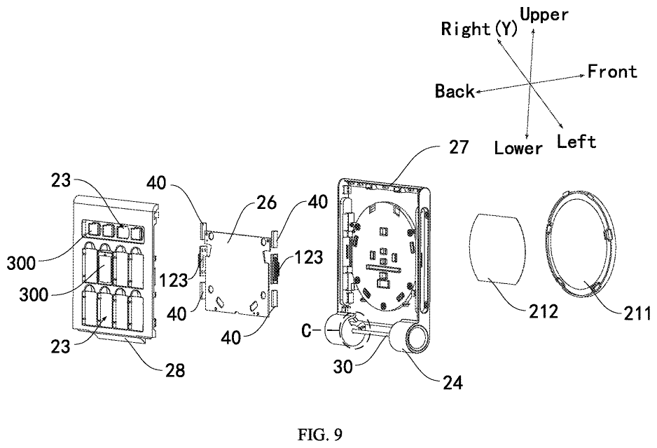

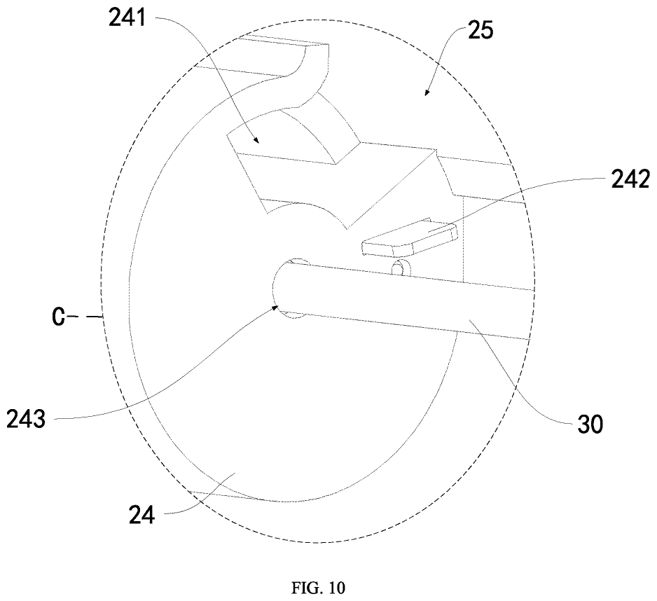

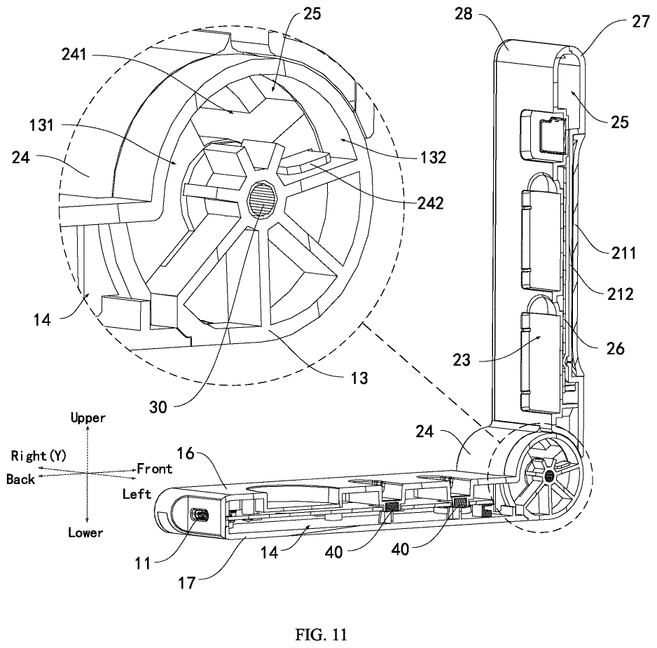

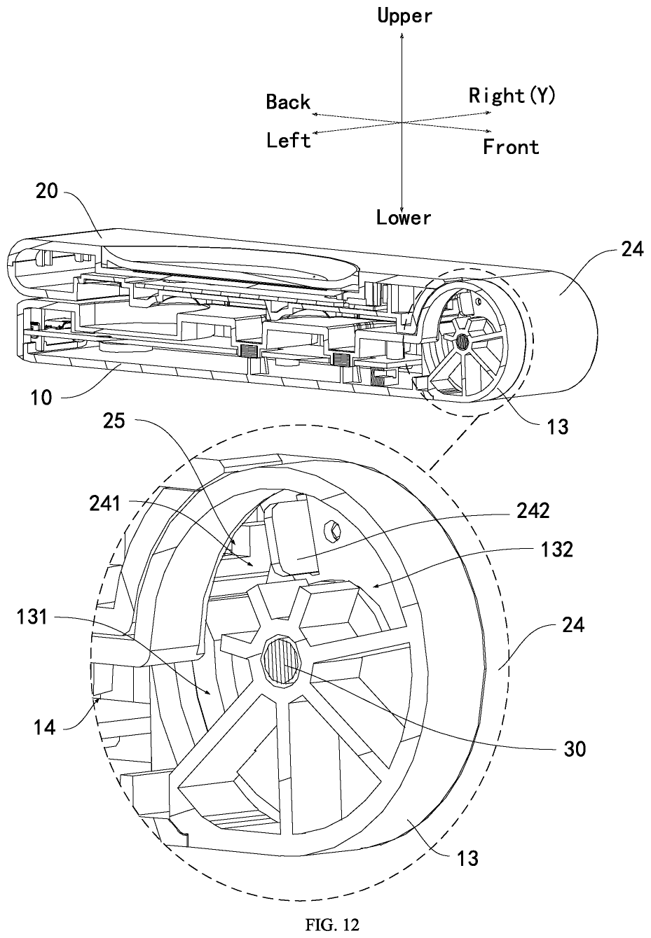

As shown in FIGS. 1-12, this embodiment relates to a charging dock 100 with a connection status display function, including a first main body 10 and a second main body 20, where the first main body 10 and the second main body 20 are hinged together. The first main body 10 is provided with a first output module 12 and an input module 11. The input module 11 is connected to a first device, and the first output module 12 is connected to a second device. The second main body 20 is provided with a display module 21, and the display module 21 is used for displaying an electrical connection status of the first output module 12 and the second device. By arranging the display module 21 on the second main body 20 hinged to the first main body 10 to display the connection status of an electronic device and the first output module 12, in an unfolded state, users may learn about the connection status of the electronic device and the first output module 12 by observing the display module 21, to avoid an improper connection between the electronic device and the output module.

In an implementation mode, the first device includes a power supply device and an information interaction device. The second device includes a device to be charged and a device to be subjected to information interaction.

In an implementation mode, the information interaction device includes a television, a display, a docking station, a game console, a computer, an iPad and a mobile phone. The device to be subjected to information interaction includes a game console, a mobile phone and an iPad.

In this embodiment, in a folded state, a projection of the second main body 20 in a thickness direction coincides with the first main body 10. In the unfolded state, an extension direction of the first main body 10 is perpendicular to an extension direction of the second main body 20. Since the first main body 10 and the second main body 20 are hinged together, the charging dock 100 may be folded to be stored and is easy to carry.

In an implementation mode, in the unfolded state, an angle is formed between the extension direction of the first main body 10 and the extension direction of the second main body 20, and the angle is an acute angle or an obtuse angle. In an implementation mode, the angle between the first main body 10 and the second main body 20 is 30°-120°.

In this embodiment, the first output module 12 is arranged on one side of the first main body 10 in the thickness direction, and in the folded state, the second main body 20 covers the first output module 12, i.e., the first output module 12 is arranged on an upper surface of the first main body 10. In this way, in the unfolded state, the second main body 20 may cover the first output module 12 and the second device, thereby improving the overall aesthetics and user experience.

In an implementation mode, the first output module 12 is arranged on a left surface or a right surface of the first main body 10.

In this embodiment, the input module 11 is arranged on a side surface of the first main body 10, to be specific, on a side surface, away from the hinge joint with the second main body 20, of the first main body 10, that is, the input module 11 is arranged on a back surface of the first main body 10.

In an implementation mode, the input module 11 is arranged on a left surface or a right surface of the first main body 10.

In this embodiment, the display module 21 is arranged on a front surface of the second main body 20 (i.e., a side surface, away from the first main body 10, of the second main body 20 in the folded state), such that the display module 21 faces forward in the unfolded state, enabling users to learn about the connection status of the second device and the first output module 12 by observing the display module 21.

In an implementation mode, the display module 21 is arranged on a side surface of the second main body 20, such as a left side surface or a right side surface of the second main body 20.

As shown in FIGS. 1-5 and 8-9, the second main body 20 is provided with a second output module 22, and the second output module 22 is electrically connected to the second device. The display module 21 is used for displaying an electrical connection status of the second output module 22 and the second device. Since the second main body 20 is provided with the second output module 22, the charging dock 100 has more charging positions; and since the first main body 10 and the second main body 20 are hinged together, the charging dock 100 may be folded to be stored and is easy to carry.

As shown in FIGS. 1-5 and 8-9, a direction of relative rotation between the first main body 10 and the second main body 20 is defined as a first direction X, and a second direction Y is defined to be perpendicular to the first direction X. The second output module 22 includes two second output units 221, and the two second output units 221 are respectively arranged on two opposite sides of the second main body 20 in the second direction Y, i.e., the two second output units 221 are respectively arranged on the left side surface and the right side surface of the second main body 20. In this way, when the first main body 10 and the second main body 20 are in the folded state, the second output units 221 of the second main body 20 are still exposed to the left side surface and the right side surface of the second main body 20, such that users may connect the second device to the second output units 221.

In an implementation mode, the second output units 221 are provided with grooves, and the second device is at least partially inlaid in the grooves. First connectors 123 are arranged in the grooves, and the first connectors 123 are connected to interfaces of the second device. The second output units 221 are provided with magnetic parts 40, and the second device is provided with magnetic mating parts. When the second device is assembled on the second output units 221, the magnetic parts 40 are magnetically connected to the magnetic mating parts to magnetically connect the second device to the second main body 20, thereby improving the connection stability of the second device and the charging dock 100.

In a first alternative embodiment, the second output module 22 is arranged on the back surface of the second main body 20, such that the second output module 22 is exposed merely in the unfolded state.

In a second alternative embodiment, the second output module 22 is arranged on the front surface of the second main body 20, and the charging dock 100 may be connected to the second device in the folded state by means of the second output module 22, so as to charge the second device or exchange information with the second device.

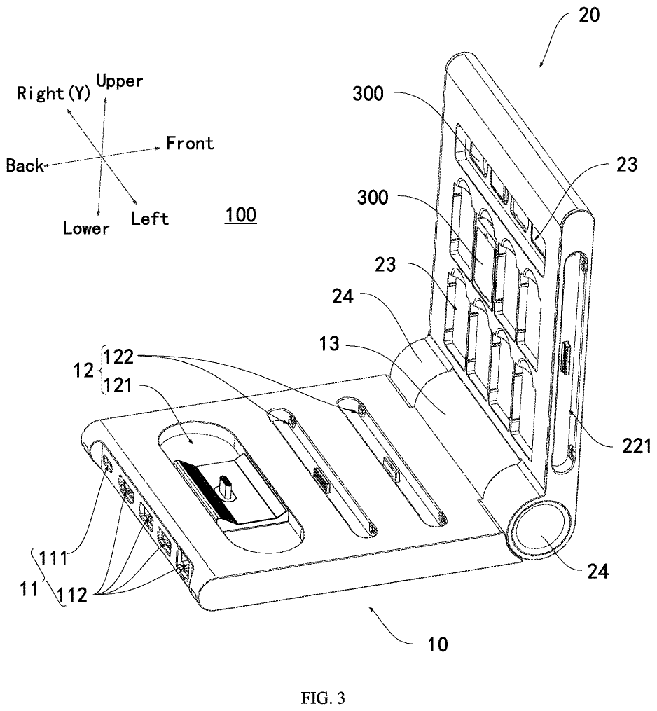

As shown in FIGS. 3-5, 9 and 11, the first main body 10 and/or the second main body 20 is provided with a storage module 23, and the storage module 23 is used for storing electronic cards 300. In this way, the electronic cards 300 may be stored conveniently, and the electronic cards 300 and the second device may be placed together to be used by users at the same time.

In this embodiment, the storage module 23 is arranged on the second main body 20. In an implementation mode, the storage module 23 is arranged on the back surface of the second main body 20. The storage module 23 includes a plurality of card slots, where the card slots include card slots suitable for large electronic cards 300 as well as card slots suitable for small electronic cards 300.

In a first alternative embodiment, the storage module 23 is arranged on the front surface of the second main body 20, such that users may observe and take the electronic cards 300 conveniently, thereby improving user experience.

In a second alternative embodiment, the storage module 23 is arranged on the first main body 10. In an implementation mode, the storage module 23 is arranged on the upper surface of the first main body 10, such that users may observe and take the electronic cards 300 conveniently, thereby improving user experience.

In this embodiment, the card slots of the storage module 23 are card slots allowing the electronic cards 300 to be assembled therein in a thickness direction, such that when the first main body 10 and the second main body 20 are folded, the electronic cards 300 in the storage module 23 may be hidden between the first main body 10 and the second main body 20 to be carried conveniently, and the overall aesthetics and user experience are improved.

In an implementation mode, the card slots of the storage module 23 are card slots allowing the electronic cards 300 to be assembled therein in a length direction.

As shown in FIGS. 3-5 and 11, the input module 11 includes a charging interface 111 and information interaction interface 112. The charging interface 111 is connected to a power supply device to charge the second device. The information interaction interface 112 is connected to an information interaction device to implement information interaction with the second device to be subjected to information interaction.

In an implementation mode, the input module 11 is only provided with the charging interface 111 or the information interaction interface 112.

In this embodiment, the first output module 12 includes a first output unit 121 and a third output unit 122, where the first output unit 121 is connected to the second device to be charged, the third output unit 122 is connected to the second device to be subjected to information interaction, and the third output unit 122 is able to charge the second device.

In an implementation mode, the first output unit 121 and the third output unit 122 are provided with grooves, and the second device is at least partially inlaid in the grooves. A second connector 124 is arranged in the groove of the first output unit 121, and the second connector 124 is connected to an interface of the second device. The third output unit 122 is provided with magnetic parts 40, and the second device is provided with magnetic mating parts. When the second device is assembled on the third output unit 122, the magnetic parts 40 are magnetically connected to the magnetic mating parts to magnetically connect the second device to the first main body 10, thereby improving the connection stability of the second device and the charging dock 100. A first connector 123 is arranged in the groove of the third output unit 122.

In an implementation mode, the first output unit 121 is provided with magnetic parts 40, and the second device is provided with magnetic mating parts. When the second device is assembled on the first output unit 121, the magnetic parts 40 are magnetically connected to the magnetic mating parts to magnetically connect the second device to the first main body 10, thereby improving the connection stability of the second device and the charging dock 100.

As shown in FIGS. 1-12, the first main body 10 is provided with a hinge portion 13, and the second main body 20 is provided with a second hinge portion 24. The second hinge portion 24 and the first hinge portion 13 are rotatably connected, such that the first main body 10 and the second main body 20 are hinged together.

In this embodiment, the first hinge portion 13 is provided with a first shaft hole 133, the second hinge portion 24 is provided with a second shaft hole 243, and a rotating shaft 30 is inlaid in the first shaft hole 133 and the second shaft hole 243 to rotatably connect the first hinge portion 13 to the second hinge portion 24, such that the first main body 10 and the second main body 20 are hinged together.

In another implementation mode, one of the first hinge portion 13 and the second hinge portion 24 is provided with a shaft hole, the other one of the first hinge portion 13 and the second hinge portion 24 is provided with a protruding shaft, and the protruding shaft is inlaid in the shaft hole to rotatably connect the first hinge portion 13 to the second hinge portion 24, such that the first main body 10 and the second main body 20 are hinged together.

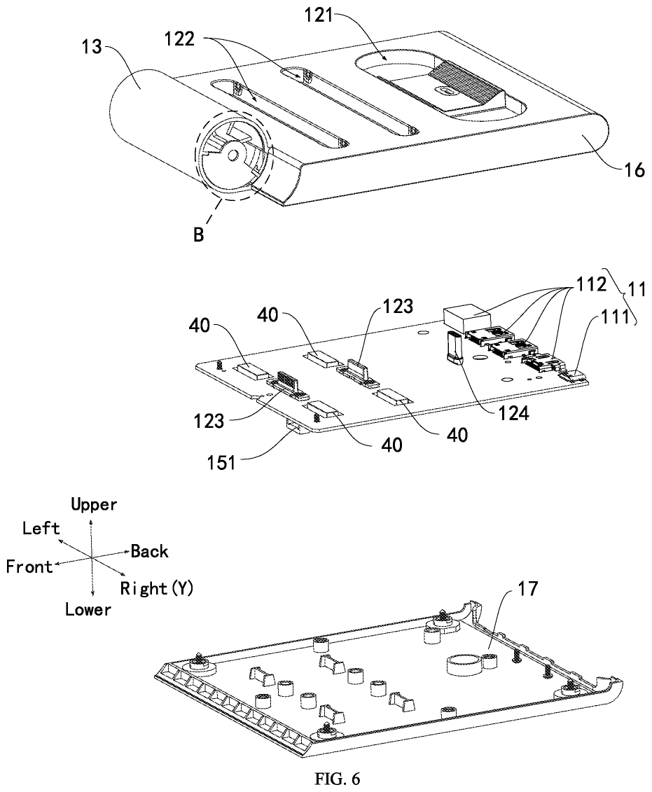

As shown in FIGS. 6-7 and 9-12, a first circuit board 15 is arranged in the first main body 10, the first circuit board 15 is electrically connected to the input module 11, and the first circuit board 15 is also electrically connected to the first output module 12. A second circuit board 26 is arranged in the second main body 20, the second circuit board 26 is electrically connected to the second output module 22, and the second circuit board 26 is also electrically connected to the first circuit board 15.

In an implementation mode, the first hinge portion 13 is provided with a first wiring duct 131, and the first wiring duct 131 communicates with the space where the first circuit board 15 is received. The second hinge portion 24 is provided with a second wiring duct 241, and the second wiring duct 241 communicates with the space where the second circuit board 26 is received and also communicates with the first wiring duct 131. A lead may be led out from a first connecting portion 151 of the first circuit board 15 and extend through the first wiring duct 131 and the second wiring duct 241 to be connected to a second connecting portion 261 of the second circuit board 26, such that the first circuit board 15 and the second circuit board 26 are electrically connected.

As shown in FIGS. 6-7 and 11-12, one of the first hinge portion 13 and the second hinge portion 24 is provided with a limiting groove 132, and the other one of the first hinge portion 13 and the second hinge portion 24 is provided with a limiting portion 242. When the first main body 10 and the second main body 20 rotate relatively, the limiting portion 242 moves in the limiting groove 132. When the second main body 20 rotates to a limit position, the limiting portion 242 abuts against an edge of the limiting groove 132 to restrain the first main body 10 and the second main body 20 from rotating relatively.

The limit position is a relative position of the second main body 20 with respect to the first main body 10 when the angle between the first main body 10 and the second main body 20 in the unfolded state is maximized.

In this embodiment, the limiting groove 132 is formed in the first hinge portion 13, and the limiting portion 242 is arranged on the second hinge portion 24. The limiting portion 242 at least partially extends in a direction from the second hinge portion 24 to the first hinge portion 13, and the limiting groove 132 communicates with the first wiring duct 131.

In an implementation mode, the limiting groove 132 is formed in the second hinge portion 24, and the limiting portion 242 is arranged on the first hinge portion 13. The limiting portion 242 at least partially extends in a direction from the first hinge portion 13 to the second hinge portion 24, and the limiting groove 132 is spaced apart from the second wiring duct 241, such that the lead may extend through the second wiring duct 241 without being affected by the limiting portion 242.

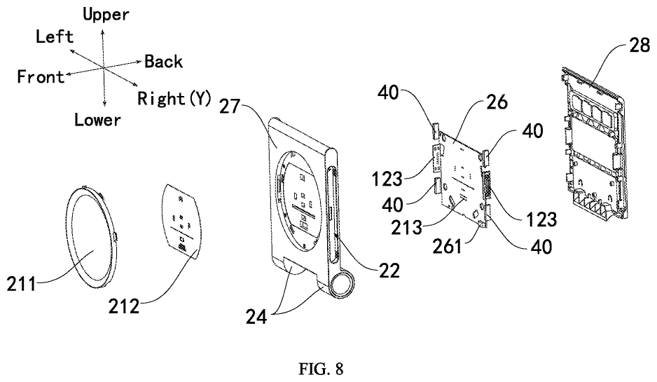

As shown in FIGS. 8-9 and 11, the display module 21 includes a diffuser 211, a light-shielding portion 212 and the light source 213 which are stacked in sequence.

In this embodiment, the light source 213 is an LED bead, the bead is arranged on the second circuit board 26, and an avoidance hole for avoiding the bead is formed in the second main body 20. The light-shielding portion 212 is arranged on an outer side of the second main body 20 to cover the avoidance hole in the second main body 20. A through-hole is formed in the light-shielding portion 212, and the through-hole is shaped like a specific pattern and aligned with the avoidance hole, such that light presenting the specific pattern is transmitted out. The diffuser 211 covers a side, facing away from the second main body 20, of the light-shielding portion 212, and the diffuser 211 is semitransparent or fully transparent to allow light to pass through.

In an implementation mode, the display module 21 is a display screen.

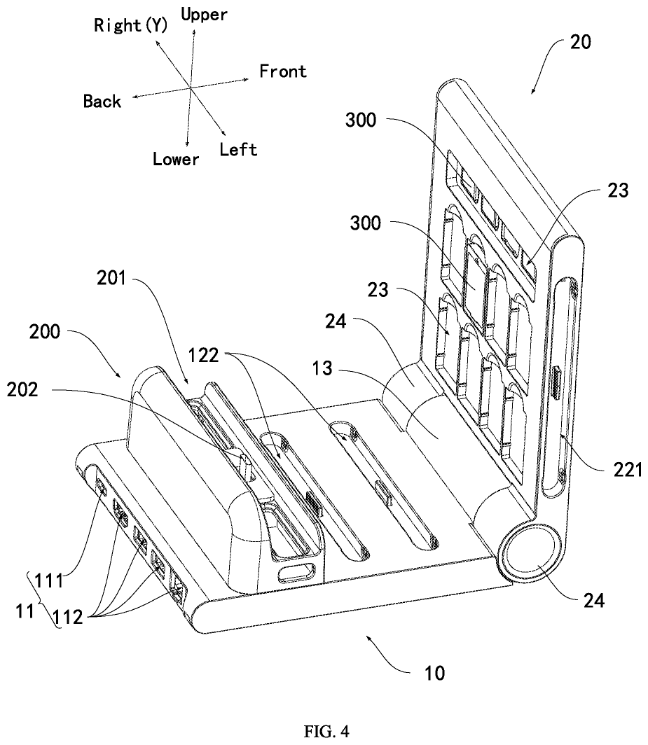

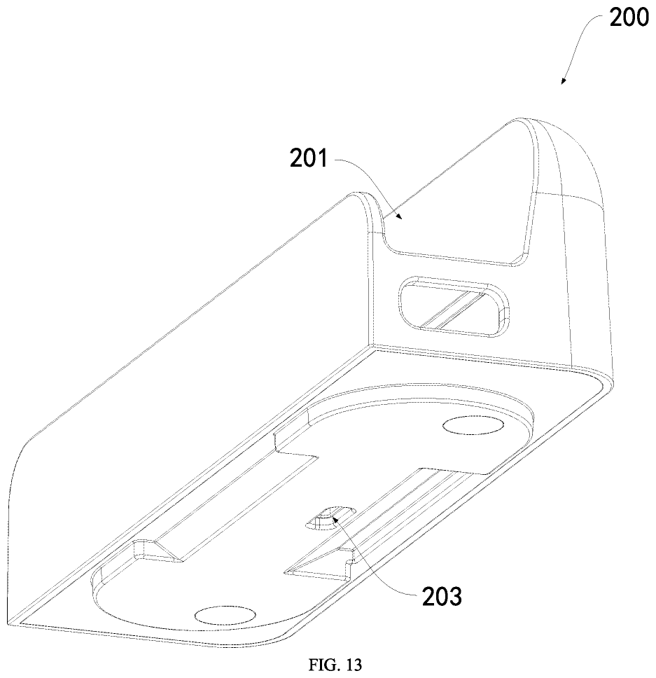

As shown in FIGS. 4-5 and 13, a charging device includes an adapter 200 and the charging dock 100. The adapter 200 may be assembled on the charging dock 100, to be specific, on the first output module 12 of the first main body 10. The adapter 200 is provided with a receiving slot 201. An adapting plug 202 is arranged in the receiving slot 201 and connected to the second device, and an adapting socket 203 is formed in the bottom of the adapter 200 and connected to the first output module 12, such that the first output module 12 and the second device are connected, i.e., the charging dock 100 and the second device are connected.

In this embodiment, the first main body 10 includes a first shell 16 and a second shell 17, the first shell 16 and the second shell 17 define a first receiving chamber 14 jointly, and the first circuit board 15 is received in the first receiving chamber 14. The second main body 20 includes a third shell 27 and a fourth shell 28, the third shell 27 and the fourth shell 28 define a second receiving chamber 25 jointly, and the second circuit board 26 is received in the second receiving chamber 25.

The above embodiment is merely used for explaining the technical solution of the present disclosure rather than limiting the present disclosure. Other modifications or equivalent substitutions made by those ordinarily skilled in the art without departing from the spirit and scope of the technical solution of the present disclosure should also fall within the scope of the claims of the present disclosure.

What is claimed is:

1. A charging dock with a connection status display function, comprising a first main body, the first main body being provided with a first output module and an input module, the input module being connected to a first device, and the first output module being electrically connected to a second device, wherein the charging dock further comprises a second main body hinged to the first main body, the second main body is provided with a display module, and the display module is used for displaying an electrical connection status of the first output module and the second device.

2. The charging dock according to claim 1, wherein the second main body is provided with a second output module, and the second output module is electrically connected to the second device.

3. The charging dock according to claim 1, wherein the first main body and/or the second main body is provided with a storage module, and the storage module is used for storing electronic cards.

4. The charging dock according to claim 1, wherein the input module comprises a charging port and an information interaction interface.

5. The charging dock according to claim 1, wherein the first main body is provided with a first hinge portion, the second main body is provided with a second hinge portion, and the second hinge portion and the first hinge portion are rotatably connected, such that the first main body and the second main body are hinged together.

6. The charging dock according to claim 5, wherein a first circuit board is arranged in the first main body, a second circuit board is arranged in the second main body, the first hinge portion is provided with a first wiring duct, the second hinge portion is provided with a second wiring duct, and the first wiring duct communicates with the second wiring duct to electrically connect the first circuit board to the second circuit board.

7. The charging dock according to claim 5, wherein one of the first hinge portion and the second hinge portion is provided with a limiting groove, the other one of the first hinge portion and the second hinge portion is provided with a limiting portion, and when the second main body rotates to a limit position, the limiting portion abuts against an edge of the limiting groove to restrain the first main body and the second main body from rotating relatively.

8. The charging dock according to claim 1, wherein the display module comprises a diffuser, a light-shielding portion and a light source which are stacked in sequence.

9. The charging dock according to claim 2, wherein a direction of relative rotation between the first main body and the second main body is defined as a first direction, a second direction is defined to be perpendicular to the first direction, the second output module comprises two second output units, and the two second output units are respectively arranged on two opposite sides of the second main body in the second direction.

10. The charging dock according to claim 9, wherein the second output units are provided with magnetic parts used for attracting the second device.

11. The charging dock according to claim 1, wherein the first output module comprises a first output unit and a third output unit, and at least one of the first output unit and the third output unit is provided with magnetic parts used for attracting the second device.

12. The charging dock according to claim 1, wherein the first main body and the second main body have a folded state; and in the folded state, a projection of the second main body in a thickness direction coincides with the first main body.

13. The charging dock according to claim 3, wherein the storage module is arranged on the second main body and located on a side, close to the first main body, of the second main body in a thickness direction, and the display module is arranged on a side, away from the first main body, of the second main body in the thickness direction.

14. The charging dock according to claim 13, wherein the first main body and the second main body have a folded state; and in the folded state, the storage module is hidden between the first main body and the second main body.

15. The charging dock according to claim 12, wherein the first output module is arranged on a side, close to the second main body, of the first main body in the thickness direction, such that the second main body covers the first output module in the folded state.

16. A charging device, comprising an adapter and the charging dock according to claim 1, wherein the adapter is assembled on the first output module of the charging dock to be connected to the charging dock.
